(19) United States
(12) Patent Application Publication
(10) Pub. No.: US 2013/0292165 A1
(43) Pub. Date: Nov. 7, 2013

(54) CIRCUIT BOARD

(71) Applicant: Chih-Chiang Lin, Taichung City (TW)

(72) Inventor: Chih-Chiang Lin, Taichung City (TW)

(73) Assignees: WINTEK CORPORATION, Taichung City (TW); WINTEK (CHINA) TECHNOLOGY LTD., Guangdong Province (CN)

(21) Appl. No.: 13/886,273

(22) Filed: May 3, 2013

(30) Foreign Application Priority Data
May 3, 2012 (TW) 101115794

(51) Int. Cl. H05K 1/02

(52) U.S. Cl. CPC H05K 1/0296
USPC 174/260

(57) ABSTRACT

A circuit board is provided. The circuit board is suitable for carrying a chip. The circuit board includes a dielectric layer and a first circuit layer. The first circuit layer is disposed on a first side of the dielectric layer. The first circuit layer includes a first pad and a plurality of second pads surrounding the first pad. The chip is substantially located above the first pad, and the second pads are suitable for connecting the chip, wherein at least one of the second pads has a tip pointing toward the first pad.

### CROSS-REFERENCE TO RELATED APPLICATION

This application claims the priority benefit of Taiwan application serial no. 101115794, filed on May 3, 2012. The entirety of the above-mentioned patent application is hereby incorporated by reference herein and made a part of this specification.

### TECHNICAL FIELD

The disclosure relates to a circuit board. More particularly, the disclosure relates to circuit board designed with electrostatic discharge (ESD) protection.

### BACKGROUND

Chips or integral circuits (IC) are small-sized and highly-densed electronic circuits. Regardless of manufacturing, packaging, testing, moving, or eventually assembling or using chips, chips are likely to malfunction due to electrostatic electricity damage. This is because electrostatic discharge generates a large amount of current flows that are over the extent to which semiconductor devices in chips can afford.

Generally speaking, a chip is bonded on a circuit board so as to be connected to an electronic device. When the chip itself accumulates static electricity, electrostatic discharge will result in damages to internal circuits. Alternatively, when static electricity accumulates on a circuit board, each circuit layer on this circuit board may be damaged by electrostatic discharge, and a preferable connection between the chip and the electronic device cannot be maintained. Therefore, it is necessary to release static electricity accumulating on the chip and the circuit board to maintain a preferable reliability (without being damaged by electrostatic discharge).

### SUMMARY

The disclosure provides a circuit board designed with electrostatic discharge protection.

The disclosure provides a circuit board suitable for carrying a chip. The circuit board includes a dielectric layer and a first circuit layer. The first circuit layer disposed at a first side of the dielectric layer, including a first pad and a plurality of second pads surrounding the first pad, the chip is substantially located above the first pad and the second pads are suitable for connecting the chip, wherein at least one of the second pads has a tip pointing toward the first pad.

In an embodiment of the disclosure, the circuit board has at least another of the second pads connected to the first pad.

In an embodiment of the disclosure, the chip that the circuit board is suitable for carrying includes a quad flat non-lead (QFN) chip.

In an embodiment of the disclosure, a distance between the tip of each of the second pads and the first pad is equal to or less than 0.5 millimeter.

In an embodiment of the disclosure, the second pads and the first pad are on the same plane.

In an embodiment of the disclosure, the at least one of the second pads includes a main body and the tip, the tip is disposed at an end of the main body adjacent to the first pad, a linewidth of the main body is larger than a linewidth of the tip, and the main body of the at least one of the second pads is substantially in a radial distribution centered at the first pad.

In an embodiment of the disclosure, the circuit board further includes a second circuit layer and a conductive pillar. The second circuit layer disposed at a second side of the dielectric layer, and the first side is opposed to the second side. The dielectric layer has at least one through-via, in which the conductive pillar is disposed. In addition, the first pad is electrically connected to the second circuit layer through the at least one conductive pillar.

In an embodiment of the disclosure, the second circuit layer is connected to a ground potential.

Based on the above, the second pads of the disclosure has a tipping structure, and the tipping structure points to an area of the first pad arranged for disposing the chip. Therefore, disposing the first pad does not increase the area of the circuit layout of the circuit board. When the chip or the circuit board itself accumulates static electricity, the second pads may release electrostatic charges and discharge the static electricity through the second pads to achieve electrostatic discharge protection.

### BRIEF DESCRIPTION OF THE DRAWINGS

In order to make the aforementioned and other features and advantages of the invention more comprehensible, embodiments accompanying figures are described in detail below.

FIG. 1 is a schematic cross-sectional view of a circuit board and a chip that the circuit board carries according to an embodiment of the disclosure.

FIG. 2 is a schematic top view of a first circuit layer 120 of FIG. 1.

FIG. 3 is a schematic cross-sectional view of a circuit board and a chip that the circuit board carries according to another embodiment of the disclosure.

### DETAILED DESCRIPTION OF DISCLOSED EMBODIMENTS

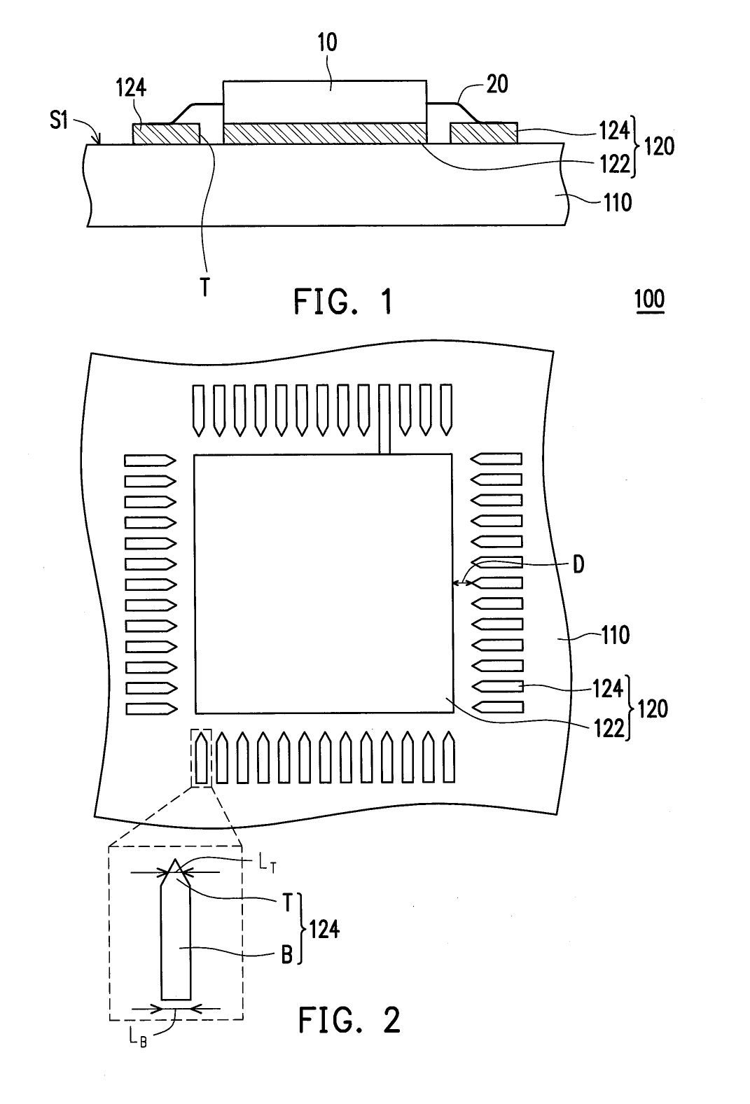

FIG. 1 is a schematic cross-sectional view of a circuit board and a chip that the circuit board carries according to an embodiment of the disclosure, and FIG. 2 is a schematic top view of a first circuit layer 120 of FIG. 1. Referring to FIGS. 1 and 2, a circuit board 100 of this embodiment is suitable for carrying a chip 10. The circuit board 100 includes a dielectric layer 110 and the first circuit layer 120. The first circuit layer 120 is disposed at a first side 51 of the dielectric 110. The first circuit layer 120 includes a first pad 122 and a plurality of second pads 124 surrounding the first pad 122, wherein at least one of the second pads 124 (as shown in FIG. 2) has a tip T, and the tip T points to the first pad 122. In this embodiment, the first circuit layer 120 includes at least another of the second pads 124 connected to the first pad 122. That one of the second pads 124 is connected to the first pad 122, as described herein, is only for an illustrative purpose, but the disclosure is not limited thereto. In other words, in other embodiments, each of the second pads 124 may have a tip T, and the tip T points to the first pad 122. Moreover, the second pads 124 and the first pad 122 of this embodiment are, for example, on the same plane, but other embodiments of the disclosure are not limited thereto.

In addition, the chip 10 carried by the circuit board 100 is substantially located above the first pad 122 and the second pads 124 are suitable for connecting the chip 10. In this embodiment, the chip 10 is, for example, disposed above the first pad 122, and the chip 10 is electrically connected to the second pads 124 through a plurality of metal wires by wire bonding. In other embodiments, the chip 10 may be electrically connected to the second pads 124 through a solder ball by flip chip bonding. Alternative, the chip 10 may be a chip of quad flat non-leaded (QFN) package soldered to the circuit board 100 by surface mounting technology (SMT). However, the disclosure is not limited thereto.

More specifically, each of the second pads 124 comprises a main body B and a tip T. The tip T is disposed at an end of the main body B adjacent to the first pad 122. A linewidth LB of the main body B is larger than a linewidth LT of the tip T, and the main body B of the second pads 124 is substantially in a radial distribution centered at the first pad 122. In this embodiment, the first pad 122 is, for example, a rectangle. The main bodies B of the second pads 124 are radically arranged at four sides of the rectangle, and the tips T of the second pads 124 point to the first pad 122. In this setting, the main bodies B of the second pads 124 have extending directions intersecting at (even perpendicular to) the four sides of the rectangle. A distance D between the tip T of each of the second pads 124 and the first pad 122 is equal to or less than 0.5 millimeter, but the disclosure is not limited thereto. In other embodiments, the first pad 122 may be in a different shape, and the distance D between the tip T of each of the second pads 124 and the first pad 122 may differ to meet a different need.

When the chip 10 itself accumulates static electricity or external static electricity accumulates on the circuit board 100, the static electricity is released onto the first pad 122 by point-discharging electricity by the tips T of the second pads 124, thereby electrostatic discharge protection to the chip 10 and the circuit board 100 may be achieved. In this way, the chip 10 carried by the circuit board 100 of this embodiment may have an excellent reliability. Namely, the chip 10 is not easily damaged by electrostatic discharge and a malfunction of the chip 10 can be avoided.

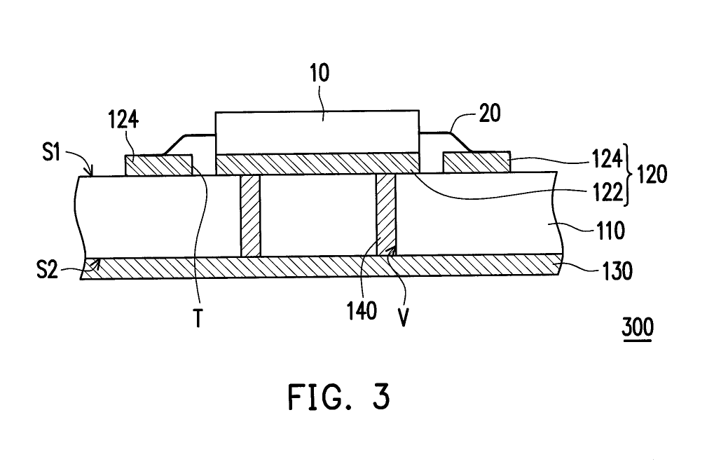

In actual practice, the circuit board 100 may include another dielectric layer and circuit layer. Another embodiment is described below for illustration. FIG. 3 is a schematic cross-sectional view of a circuit board and a chip that the circuit board carries according to another embodiment of the disclosure. Referring to FIG. 3, compared to the circuit board 100 described in the previous embodiment, a circuit board 300 of this embodiment may further include a second circuit layer 130 and at least one conductive pillar 140. The second circuit layer 130 is disposed at a second side S2 of the dielectric layer 110, wherein the first side S1 is opposed to the second side S2. The dielectric layer 110 has at least one through-via V, in which the conductive pillar 140 is disposed. In addition, the first pad 122 is electrically connected to the second circuit layer 130 through the at least one conductive pillar 140. A number of the through-vias V and the conductive pillars 140 is set at 2 as an example for the description herein. However, the number is not limited thereto. It should be noted that this embodiment merely exemplarily illustrates the structure of the dielectric layer 110 and the circuit layers (including the first circuit layer 120 and the second circuit layer 130) of the circuit board 300. In actual practice, the circuit board 300 may further include another dielectric layer and circuit layer or an encapsulant layer disposed above the first circuit layer 120, and the disclosure does not specifically set the number of film layers of the dielectric layers and circuit layers.

A material of the first pad 122 of the first circuit layer 120 may be, for example, a material with excellent electric and thermal conductivities. In other words, the first pad 122 may provide excellent heat dissipation for the chip 10 in addition to carrying the chip 10. Moreover, since the first pad 122 is electrically connected to the second circuit layer 130, in this embodiment, the first pad 122 may have a ground connection by connecting the second circuit layer 130 to a ground potential. Consequently, when the chip 10 itself accumulates static electricity or external static electricity accumulates on the circuit board 300, the static electricity is conducted to the first pad 122 and released through the second circuit layer 130 by point-discharging electricity by the tips T of the second pads 124, thereby electrostatic discharge protection to the chip 10 and the circuit board 300 may be enabled. In this way, the chip 10 carried by the circuit board 300 of this embodiment may have an excellent reliability. Namely, the chip 10 is not easily damaged by electrostatic discharge and a malfunction of the chip 10 can be avoided.

In this embodiment, the first pad 122 located below the chip 10 is electrically connected through the conductive pillar 140 to the second circuit layer 130 connecting to the ground potential. Therefore, the first circuit layer 120 of the circuit board 300 of this embodiment needs not to be disposed with an additional grounding circuit in addition to an area in which the chip 10 is located to release electrostatic charges, thereby an area of circuit layout is reduced. Moreover, since the second circuit layer 130 is disposed at a side (the second side S2) of the dielectric layer 110 distant from the chip 10, an area of the second circuit layer 130 connecting to the ground potential may be increased to further improve electrostatic discharge protection of the circuit board 300 without influencing an area of a circuit layout of the first circuit layer 120.

Given the above, in the circuit board of the disclosure, the second pads surrounding the chips are disposed with the tips pointing to the first pad, and the first pad carrying the chip may be electrically connected through the conductive pillar to the second circuit layer connecting to the ground potential. In this way, when the chip itself accumulates static electricity, the second pads are capable of tip-discharging to release static charges to the first pad. Thereby, the electrostatic protection of the circuit board is improved, and the chip utilizing this circuit board has a better reliability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit board suitable for carrying a chip, comprising
a dielectric layer; and
a first circuit layer, disposed at a first side of the dielectric layer, comprising a first pad and a plurality of second pads surrounding the first pad, the chip is substantially located above the first pad and the second pads are suitable for connecting the chip, wherein at least one of the second pads has a tip pointing toward the first pad.

2. The circuit board as claimed in claim 1, wherein at least one of the second pads without the tip is connected to the first pad.

3. The circuit board as claimed in claim 1, wherein the chip that the circuit board is suitable for carrying comprises a quad flat non-leaded chip.

4. The circuit board as claimed in claim 1, wherein a distance between the tip of each of the second pads and the first pad is equal to or less than 0.5 millimeter.

5. The circuit board as claimed in claim 1, wherein the second pads and the first pad are on the same plane.

6. The circuit board as claimed in claim 1, wherein the at least one of the second pads comprises a main body and the tip, the tip is disposed at an end of the main body adjacent to the first pad, a linewidth of the main body is larger than a linewidth of the tip, and the main body of the at least one of the second pads is substantially in a radial distribution centered at the first pad.

7. The circuit board as claimed in claim 1, further comprising:
a second circuit layer disposed at a second side of the dielectric layer, and the first side is opposed to the second side; and
at least one conductive pillar, wherein the dielectric layer has at least one through-via, the conductive pillar is disposed in the at least one through-via, and the first pad is electrically connected to the second circuit layer through the at least one conductive pillar.

8. The circuit board as claimed in claim 7, wherein the second circuit layer is connected to a ground potential.
